(19) United States
(12) Patent Application Publication
(10) Pub. No.: US 2021/0036163 A1
(43) Pub. Date: Feb. 4, 2021

(54) THIN FILM TRANSISTOR AND PRODUCTION METHOD THEREFOR

(71) Applicant: SAKAI DISPLAY PRODUCTS CORPORATION, Sakai-shi, Osaka (JP)

(72) Inventor: HIROYUKI OHTA, Sakai-shi, Osaka (JP)

(21) Appl. No.: 16/968,045

(22) PCT Filed: Mar. 9, 2018
(86) PCT No.: PCT/JP2018/009287

§ 371 Date: Aug. 6, 2020

(51) Int. Cl. H01L 29/786; H01L 21/02; H01L 29/66; H01L 27/12

(52) U.S. Cl. CPC H01L 29/78678; H01L 21/0262; H01L 21/02592; H01L 21/02675; H01L 29/78696; H01L 27/1222; H01L 21/02532; H01L 27/1274; H01L 29/66765

(57) ABSTRACT

A thin film transistor (101) includes: a gate electrode (2) supported on a substrate (1); a semiconductor layer (4) including a crystalline silicon region (4c), wherein the crystalline silicon region (4c) includes a channel region (Rc); a gate insulating layer (3); a source electrode (8s); and a drain electrode (8d), wherein the channel region (Rc) includes a plurality of first crystalline regions (C1) and at least one second crystalline region (C2), wherein the first crystalline regions (C1) are separated from each other by the second crystalline region (C2); each first crystalline region (C1) includes an n-type impurity at a higher concentration than the second crystalline region (C2); and an average grain diameter of silicon crystal grains in each first crystalline region (C1) is larger than an average grain diameter of silicon crystal grains in the second crystalline region (C2).

### TECHNICAL FIELD

The present invention relates to a thin film transistor using crystalline silicon, and a method for manufacturing the same.

### BACKGROUND ART

Thin film transistors (hereinafter “TFTs”) are used as switching elements in an active matrix substrate, for example. In the present specification, such TFTs will be referred to as “pixel TFTs”. Non-crystalline silicon TFTs that use an amorphous silicon film (hereinafter abbreviated as “a-Si film”) as the active layer, crystalline silicon TFTs that use a crystalline silicon film (hereinafter abbreviated as “c-Si film”) such as a polycrystalline silicon film as the active layer, etc., have been widely used as pixel TFTs. Generally, because the field effect mobility of a c-Si film is higher than the field effect mobility of an a-Si film, a crystalline silicon TFT has a higher current driving force (i.e., a larger ON current) than a non-crystalline silicon TFT.

In an active matrix substrate used in a display device, or the like, a c-Si film to be the active layer of a crystalline silicon TFT is formed by, for example, forming an a-Si film on a glass substrate, and then crystalizing the a-Si film through irradiation with a laser beam (laser annealing). A method for scanning the entire surface of an a-Si film with a linear laser beam has been known in the art as a crystallization method using laser annealing. Also, a method has been proposed in the art in which an a-Si film is partially crystallized by focusing a laser beam only on a region of the a-Si film that is to be the active layer of the TFT (Patent Document Nos. 1 to 3).

### CITATION LIST

### Patent Literature

Patent Document No. 1: International Publication WO2011/132559 pamphlet

Patent Document No. 2: International Publication WO2016/157351 pamphlet

Patent Document No. 3: International Publication WO2016/170571 pamphlet

### SUMMARY OF INVENTION

### Technical Problem

For crystalline silicon TFTs, there is a demand for further enhancing the channel mobility to improve the ON characteristic.

One embodiment of the present invention has been made in view of the above, and an object thereof is to provide a thin film transistor that can have a high ON characteristic, and a method for manufacturing the same.

### Solution to Problem

A thin film transistor according to one embodiment of the present invention includes: a substrate; a gate electrode supported on the substrate; a semiconductor layer including a crystalline silicon region, wherein the crystalline silicon region includes a first region and a second region, and includes a channel region that is located between the first region and the second region and overlaps with the gate electrode as viewed from a direction normal to the substrate; a gate insulating layer that provides insulation between the gate electrode and the semiconductor layer; a source electrode electrically connected to the first region; and a drain electrode electrically connected to the second region, wherein: the channel region includes a plurality of first crystalline regions and at least one second crystalline region, wherein the first crystalline regions are separated from each other by the at least one second crystalline region; each of the first crystalline regions includes an n-type impurity at a higher concentration than the at least one second crystalline region; and an average grain diameter of silicon crystal grains in each of the first crystalline regions is larger than an average grain diameter of silicon crystal grains in the at least one second crystalline region.

In one embodiment, the at least one second crystalline region does not substantially include an n-type impurity.

In one embodiment, the semiconductor layer further includes a concentration gradient region in a boundary between the at least one second crystalline region and one of the first crystalline regions, wherein a concentration of an n-type impurity of the concentration gradient region decreases from the one of the first crystalline regions toward the at least one second crystalline region.

In one embodiment, silicon crystal grains in the first crystalline regions and the at least one second crystalline region have a columnar shape that extends in a thickness direction of the semiconductor layer.

In one embodiment, the average grain diameter of silicon crystal grains in each of the first crystalline regions is 50 nm or more and 170 nm or less, and the average grain diameter of silicon crystal grains in the at least one second crystalline region is 30 nm or more and 100 nm or less.

In one embodiment, the semiconductor layer is formed by laser-annealing an amorphous silicon film wherein islands including the n-type impurity are arranged discretely on an upper surface or a lower surface of the amorphous silicon film.

In one embodiment, the thin film transistor further includes a protection layer that covers the channel region between the semiconductor layer and the source electrode and the drain electrode.

In one embodiment, the semiconductor layer further includes a non-crystalline silicon region.

In one embodiment, the n-type impurity includes phosphorus.

A semiconductor device according to one embodiment of the present invention is a semiconductor device including any of the thin film transistors set forth above, wherein: the semiconductor device has a display area including a plurality of pixels; and the thin film transistor is arranged in each of the pixels of the display area.

A method for manufacturing a thin film transistor according to one embodiment of the present invention is a method for manufacturing a thin film transistor supported on a substrate, including: a step of forming a semiconductor layer to be an active layer of the thin film transistor, wherein the step of forming the semiconductor layer includes: a semiconductor film formation step (A) of forming a semiconductor film including an n-type impurity, the step (A) including a step (a1) of forming a non-crystalline silicon film on the substrate, and a step (a2), before or after the step (a1), of discretely forming a plurality of n-type impurity-containing islands including the n-type impurity; and a crystallization step (B) of crystallizing at least a portion of the semiconductor film through irradiation with a laser beam so as to form a crystalline silicon region in the at least a portion of the semiconductor film, wherein a crystalline region is formed in a portion of the at least a portion of the semiconductor film where the n-type impurity-containing islands are located, the crystalline region having a larger crystal grain diameter than in a portion of the at least a portion of the semiconductor film where the n-type impurity-containing islands are not located.

In one embodiment, in the step (a2), the n-type impurity-containing islands are formed by utilizing an initial growth stage of deposition by a CVD method.

In one embodiment, the method further includes, between the step (A) and the step (B), a step of forming an insulating film that covers the semiconductor film, wherein in the step (B), the semiconductor film is irradiated with the laser beam from above the insulating film.

### Advantageous Effects of Invention

One embodiment of the present invention provides a thin film transistor that can have a high ON characteristic, and a method for manufacturing the same.

### BRIEF DESCRIPTION OF DRAWINGS

FIGS. 1(a) and 1(b) are a schematic plan view and a schematic cross-sectional view, respectively, of a TFT 101 of a first embodiment, and FIGS. 1(c) and 1(d) are an enlarged plan view and an enlarged cross-sectional view, respectively, illustrating the polycrystal structure of a c-Si region 4c in the TFT 101.

FIGS. 2(a) and 2(b) are an enlarged plan view and an enlarged cross-sectional view, respectively, further illustrating the polycrystal structure of the c-Si region 4c.

FIGS. 3(a) and 3(b) are schematic step-by-step cross-sectional views illustrating a method forming a semiconductor layer 4 in the TFT 101.

FIGS. 4(a) and 4(b) are schematic cross-sectional views each showing another example of the semiconductor film 40.

FIGS. 5(a) to 5(f) are schematic step-by-step cross-sectional views illustrating an example of a method for manufacturing the TFT 101.

FIGS. 6(a) to 6(c) are schematic step-by-step cross-sectional views illustrating a variation of a method for manufacturing the TFT 101.

FIG. 7 is a schematic diagram illustrating the V-I characteristic of the TFT 101.

FIGS. 8(a) and 8(b) are a schematic plan view and a schematic cross-sectional view of a TFT 102 of a second embodiment.

FIGS. 9(a) to 9(d) are schematic step-by-step cross-sectional views illustrating an example of a method for manufacturing the TFT 102.

### DESCRIPTION OF EMBODIMENTS

As described above, there is a demand for further enhancing the channel mobility of a TFT using crystalline silicon (c-Si).

The channel mobility of a crystalline silicon TFT has a correlation with the grain size of c-Si (the grain diameter of Si crystal grains) in the active layer of the crystalline silicon TFT, for example. That is, the channel mobility improves as the average grain diameter of c-Si crystal grains increases.

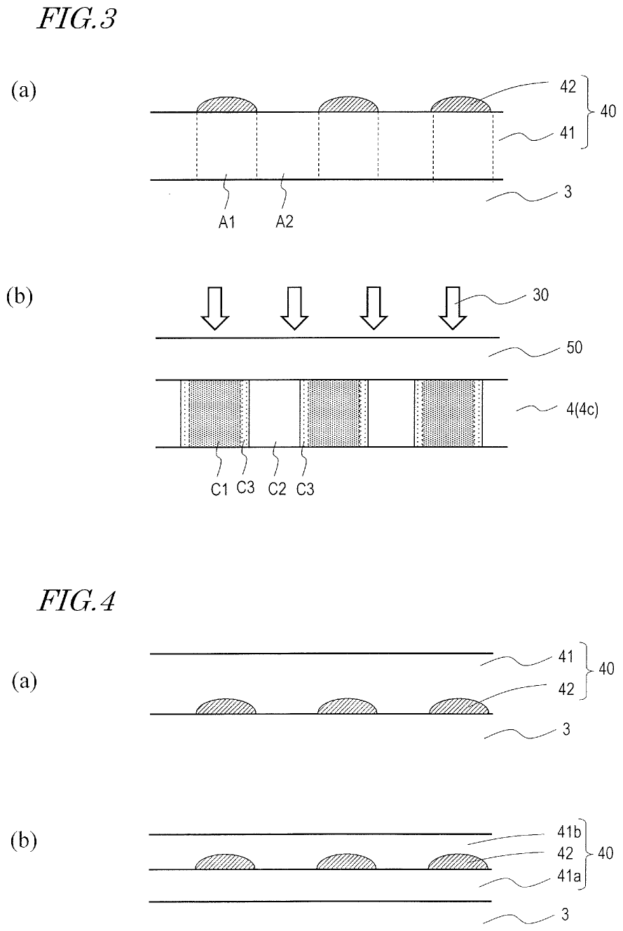

The grain diameter of Si crystal grains can be controlled based on laser irradiation conditions used for crystallizing an a-Si film by a laser annealing method, for example. However, there is a limit to the control of the grain diameter based on laser irradiation conditions. Journal of the surface science society of Japan, Vol. 24, No. 6, pp. 375-382, 2003 states that the average grain diameter of Si crystal grains depends on laser fluence (laser power density) and is maximized at a fluence at the boundary between the partially melted state and the completely melted state of Si. According to this document, the maximum value of the average grain diameter of Si crystal grains is about 130 nm (see FIG. 4 of this document). Further increasing the average grain diameter requires an approach other than to control laser irradiation conditions.

On the other hand, Journal of the surface science society of Japan, Vol. 19, No. 10, pp. 624-629, 1998 discloses that a c-Si film having a large average grain diameter is formed when a phosphorus-doped a-Si film is crystallized by laser. However, the method disclosed in this document results in a low electric resistance of the c-Si film. Therefore, using this c-Si film as the active layer of a TFT leads to problems such as an increase in the off-leak current and conduction between the source and the drain of the TFT, thus failing to achieve desired TFT characteristics.

In view of this, the present inventor found that it is possible to make use of the fact that the size of crystal grains can be increased by adding an n-type impurity element such as phosphorus to an a-Si film, and to thereby further improve the channel mobility while suppressing the decrease of the off resistance by arranging, discretely in the channel region, crystalline regions where the size of Si crystal grains is large.

A thin film transistor according to one embodiment of the present invention will now be described with reference to the drawings.

### First Embodiment

A thin film transistor (TFT) according to a first embodiment of the present invention is an etch stop-type crystalline silicon TFT having a bottom gate structure. The TFT of the present embodiment is applicable to circuit substrates such as active matrix substrates, various display devices such as liquid crystal display devices and organic EL display devices, image sensors, electronic appliances, etc.

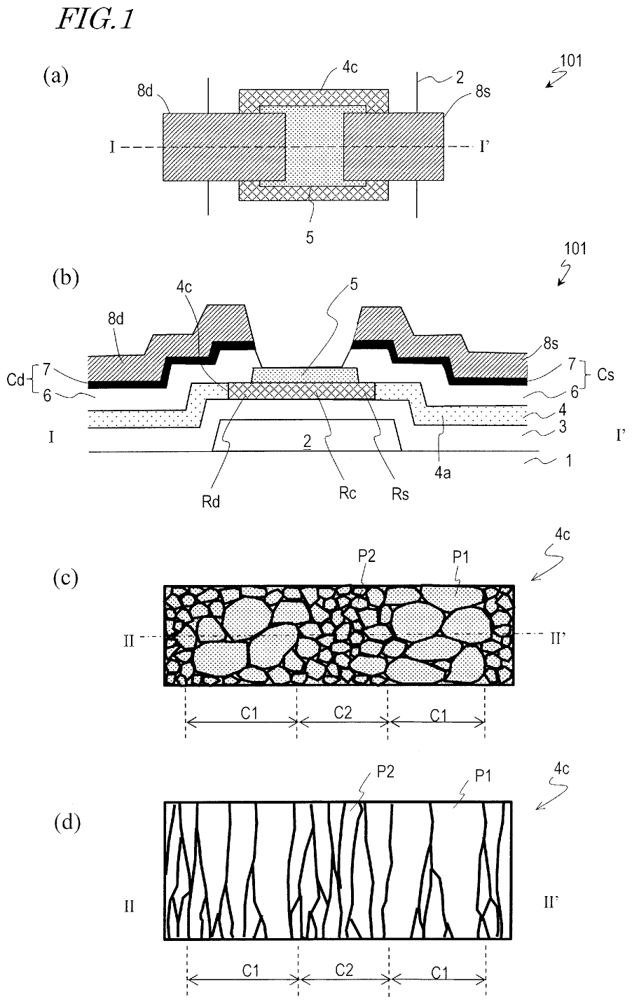

FIG. 1(a) is a schematic plan view of a thin film transistor (TFT) 101 in a semiconductor device of the present embodiment, and FIG. 1(b) is a cross-sectional view of the TFT 101 taken along line I-I′.

The TFT 101 is supported on a substrate 1 such as a glass substrate, and includes a gate electrode 2, a semiconductor layer (active layer) 4, a gate insulating layer 3 that provides insulation between the gate electrode 2 and the semiconductor layer 4, and a source electrode 8s and a drain electrode 8d that are electrically connected to the semiconductor layer 4.

In this example, the gate electrode 2 is arranged on the substrate 1 side of the semiconductor layer 4 with the gate insulating layer 3 therebetween (bottom gate structure). A protection layer (referred to also as an etch stop layer) 5 is arranged on the semiconductor layer 4 so as to be in contact with a portion of the semiconductor layer 4. A first contact layer Cs and a second contact layer Cd are provided between the semiconductor layer 4 and the source electrode 8s and the drain electrode 8d, respectively. The source electrode 8s is electrically connected to a portion of the semiconductor layer 4 with the first contact layer Cs therebetween. The drain electrode 8d is electrically connected to another portion of the semiconductor layer 4 with the second contact layer Cd therebetween.

The semiconductor layer 4 is a layer that functions as the active layer of the TFT 101, and includes a crystalline silicon region (c-Si region) 4c that primarily includes polycrystalline silicon. At least a portion of the c-Si region 4c is arranged so as to overlap with the gate electrode 2 with the gate insulating layer 3 therebetween. As shown in the figure, the semiconductor layer 4 may include the c-Si region 4c, and a non-crystalline silicon region (a-Si region) 4a that primarily includes non-crystalline silicon. Alternatively, the entire semiconductor layer 4 may be the c-Si region 4c.

The c-Si region 4c includes a channel region Rc where the channel of the TFT 101 is formed, a first region Rs that is in contact with the first contact layer Cs, and a second region Rd that is in contact with the second contact layer Cd. The first region Rs and the second region Rd are located on the opposite sides of the channel region Rc. Crystalline regions where the average grain diameter of Si crystal grains is large are arranged discretely in the c-Si region 4c (at least the channel region Rc). The polycrystal structure of the c-Si region 4c will later be described in detail.

The protection layer 5 is arranged on a portion of the semiconductor layer 4 so as to be in contact with at least a portion of the upper surface of the channel region Rc. The protection layer 5 may be in contact with the entire upper surface of the channel region Rc. Herein, the protection layer 5 has an island-shaped pattern. Note that the protection layer 5 does not need to be in an island-like pattern. In that case, the protection layer 5 may have an opening through which the first region Rs and the second region Rd of the semiconductor layer 4 are exposed.

The first contact layer Cs and the second contact layer Cd each include a silicon layer (which may be an a-Si layer or a c-Si layer) that includes a conductivity type-imparting impurity. In this example, the first contact layer Cs and the second contact layer Cd each include a first a-Si layer 6 that is in contact with the semiconductor layer 4, and a second a-Si layer 7 that is arranged on the first a-Si layer 6. The second a-Si layer 7 includes a conductivity type-imparting impurity, and has a higher conductivity than the first a-Si layer 6. The first a-Si layer 6 may be, for example, an intrinsic silicon layer that does not substantially include an impurity, and the second a-Si layer 7 may be, for example, an n⁺-type a-Si layer doped with an n-type-imparting impurity. Note that the first contact layer Cs and the second contact layer Cd may each have a single-layer structure of a silicon layer (e.g., an n⁺-type a-Si layer) including a conductivity-imparting impurity.

At least the silicon layers including a conductivity-imparting impurity (e.g., n⁺-type a-Si layers or the second a-Si layers 7 in this example) of the first contact layer Cs and the second contact layer Cd are arranged spaced apart from each other. As illustrated in FIG. 1, for example, the first and second a-Si layers 6 and 7 of the first contact layer Cs and the second contact layer Cd may be arranged spaced apart from each other. Although not shown in the figures, only the second a-Si layers 7, which are an n⁺-type a-Si layer, of the first contact layer Cs and the second contact layer Cd may be arranged spaced apart from each other, while the first a-Si layers 6 thereof, which are an intrinsic silicon layer, are not separated.

With the TFT 101, in the ON state, a current flows from one of the source electrode 8s and the drain electrode 8d to the other. For example, when a current flows in the direction from the source electrode 8s to the drain electrode 8d, the current flows through the channel region Rc of the semiconductor layer 4, via the source electrode 8s and the first contact layer Cs, and then reaches the drain electrode 8d via the second contact layer Cd.

FIG. 1(c) and FIG. 1(d) are schematic views illustrating the polycrystal structure of the c-Si region 4c, and are an enlarged plan view showing a portion of the c-Si region 4c and an enlarged cross-sectional view taken along line II-II′, respectively.

As shown in the figures, the c-Si region 4c includes a plurality of first crystalline regions C1 and at least one second crystalline region C2. The first crystalline regions C1 are separated from each other by the second crystalline region C2.

The first crystalline regions C1 may be arranged discretely in the channel region Rc. The term “arranged discretely” as used herein means that the first crystalline regions C1 are not arranged so as to connect together the first contact layer Cs and the second contact layer Cd (i.e., the source and the drain). For example, as viewed from the direction normal to the substrate 1, the first crystalline regions C1 may be arranged in an island-like pattern in the second crystalline region C2.

Each first crystalline region C1 includes a plurality of Si crystal grains P1, and each second crystalline region C2 includes a plurality of Si crystal grains P2. The average grain diameter of Si crystal grains P1 of the first crystalline region C1 is larger than the average grain diameter of Si crystal grains P2 of the second crystalline region C2. Therefore, the first crystalline region C1 can have a higher mobility than the second crystalline region C2.

In this example, the Si crystal grains P1 and P2 are columnar grains that extend along the thickness direction of the semiconductor layer 4. The average grain diameter of Si crystal grains P1 in the first crystalline region C1 may be 50 nm or more and 170 nm or less (e.g., 75 nm), for example. The average grain diameter of Si crystal grains P2 in the second crystalline region C2 may be 30 nm or more and 100 nm or less (e.g., 45 nm), for example. The term “average grain diameter” as used herein refers to the average grain diameter of crystal grains in each crystalline region as viewed from the direction normal to the substrate 1, and is measured by observing a surface SEM (Scanning Electron Microscope), for example. An example of a method for measuring the average grain diameter of crystal grains is as follows. The semiconductor layer including a c-Si region obtained through laser irradiation is etched by using a Secco etchant including potassium dichromate (e.g., a mixed solution of 70 mg of K₂Cr₂O₄, 3 mL of 50% HF aqueous solution and 30 mL of pure water). Then, the surface of the c-Si region after being etched is observed by SEM to measure the crystal grain diameter. About ten crystal grain diameters are measured for each of the crystalline regions C1 and C2 to obtain the average grain diameter.

The first crystalline regions C1 include an n-type impurity such as phosphorus at a higher concentration than in the second crystalline region C2. The n-type impurity (e.g., phosphorus atom) is included at a higher concentration in the grain boundary portion of an Si crystal grain P1, for example, than the inside of the Si crystal grain P1. The second crystalline region C2 may be a region that does not substantially include an n-type impurity (that is not actively implanted).

The concentration of the n-type impurity in the first crystalline regions C1 may be, for example, 1×10¹⁸ cm⁻³ or more and 1×10²³ cm⁻³ or less, and preferably 5×10¹⁸ cm⁻³ or more and 1×10²³ cm⁻³ or less. If it is 1×10¹⁸ cm⁻³ or more, it is possible to more effectively increase the average grain diameter of Si crystal grains. If it is 1×10²³ cm⁻³ or less, it is possible to more reliably suppress the decrease of the off resistance of the TFT 101. On the other hand, the concentration of the n-type impurity in the second crystalline region C2 may be 1×10¹⁷ cm⁻³ or less, for example. Thus, it is possible to ensure a desired OFF characteristic because it is possible to suppress the increase of the average grain diameter in the second crystalline region C2.

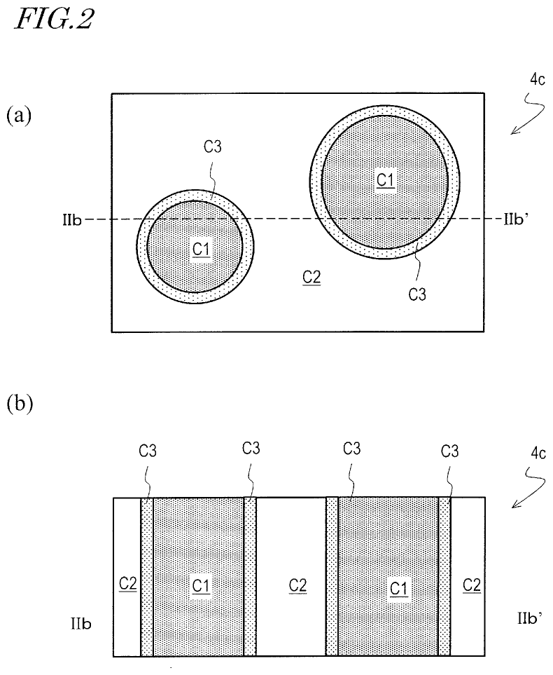

FIGS. 2(a) and 2(b) are schematic views further illustrating the polycrystal structure of the c-Si region 4c, and are an enlarged plan view and an enlarged cross-sectional view, respectively, showing a portion of the c-Si region 4c. FIG. 2(b) shows a cross section taken along line IIb-IIb′ of FIG. 2(a).

As illustrated in FIG. 2, in the boundary portions between the first crystalline regions C1 and the second crystalline regions C2, concentration gradient regions C3 may be formed, of which the concentration of the n-type impurity decreases from the first crystalline region C1 side toward the second crystalline region C2 side. The distribution of the n-type impurity can be observed by using a three-dimensional atom probe (3DAP), for example.

As shown in FIG. 2(a), as viewed from the direction normal to the substrate 1, the first crystalline regions C1 may be arranged in an island-like pattern in the second crystalline region C2.

The c-Si region 4c having a polycrystal structure as shown in FIG. 1 and FIG. 2 may be formed by performing laser annealing after islands including an n-type impurity such as phosphorus are arranged discretely in an a-Si film.

Note that although an example where the entire c-Si region 4c has the polycrystal structure described above has been described herein, at least the channel region Rc of the c-Si region 4c needs to include the first crystalline region C1 and the second crystalline region C2.

In the TFT 101 of the present embodiment, the first crystalline regions C1 where the average grain diameter of Si crystal grains is large, i.e., the mobility is high, are arranged discretely in the channel region Rc of the c-Si region 4c. Carriers move between the source and the drain through a plurality of first crystalline regions C1. Therefore, it is possible to enhance the channel mobility of the TFT as compared with a case where carriers move only through the second crystalline region C2. As a result, the threshold voltage Vth can be increased (shifted in the positive direction).

Since the first crystalline region C1 includes an n-type impurity at a higher concentration than the second crystalline region C2, the first crystalline region C1 has a lower electric resistance than the second crystalline region C2. Thus, it is possible to improve the ON current of the TFT 101 as compared with a case where the c-Si region 4c is composed only of the second crystalline region C2.

Note that in the present embodiment, the first crystalline regions C1 are arranged discretely between the first contact layer Cs and the second contact layer Cd, and they are not connected together. Therefore, arranging the first crystalline regions C1 with a low electric resistance will not lead to conduction between the source and the drain, an increase in the off-leak current, etc.

Moreover, if the concentration gradient region C3 is formed in the c-Si region 4c between the first crystalline region C1 and the second crystalline region C2, advantageous effects are realized as follows.

With conventional crystalline silicon TFTs, a leak current due to a quantum mechanical tunnel effect may occur from a high electric field between the gate and the drain (gate-induced drain leakage (GIDL)) in a region where the gate electrode and the drain electrode overlap with each other. In contrast, with the TFT 101, a depletion layer expands in the concentration gradient region C3, thereby relaxing the electric field at the drain end (LDD effect). As a result, it is possible to suppress the occurrence of the gate-induced drain leakage (GIDL).

The TFT 101 of the present embodiment can be suitably used in an active matrix substrate, for example. An active matrix substrate has a display region including a plurality of pixels, and a non-display region (referred to also as a peripheral region) other than the display region. Each pixel includes a pixel TFT as a switching element. In the peripheral region, a driving circuit such as a gate driver may be formed monolithically. A driving circuit includes a plurality of TFTs (referred to as “circuit TFTs”). The TFT 101 may be used as a pixel TFT and/or a circuit TFT.

<Method for Forming Semiconductor Layer 4>

Next, an example of a method for forming the semiconductor layer 4 including the first crystalline region C1 and the second crystalline region C2 will be described.

FIG. 3(a) and FIG. 3(b) are schematic cross-sectional views illustrating a method for forming the semiconductor layer 4 in the TFT 101.

First, as shown in FIG. 3(a), an a-Si film 41 is deposited on the gate insulating layer 3 by a CVD method, for example. The a-Si film 41 may be a non-doped amorphous silicon film that does not substantially include an n-type impurity. A non-doped amorphous silicon film refers to an a-Si film that is formed without actively adding an n-type impurity (e.g., using a source gas that does not include an n-type impurity). Note that the a-Si film 41 may include an n-type impurity at a relatively low concentration.

Then, a plurality of islands (hereinafter referred to as “n-type impurity-containing islands”) 42 that include an n-type impurity (e.g., phosphorus) at a higher concentration than the a-Si film 41 are formed spaced apart from each other on the a-Si film 41 by a CVD method. The n-type impurity-containing islands 42 can be formed by utilizing the initial growth stage of deposition by a CVD method. For example, the n-type impurity-containing islands 42 may be formed by depositing a film including an n-type impurity in an island-like pattern, which is realized by controlling the deposition conditions such as the deposition time. Thus, the semiconductor film 40 to be the active layer of the TFT 101 is obtained. The semiconductor film 40 includes first non-crystalline regions A1 where the n-type impurity-containing islands 42 are formed (which include the a-Si film 41 and the n-type impurity-containing islands 42), and second non-crystalline regions A2 that are composed only of the a-Si film 41.

The n-type impurity-containing island 42 may be an a-Si film (doped amorphous silicon film) including an n-type impurity. Alternatively, it may be an insulating film including an n-type impurity. For example, an insulating film obtained by doping the same film as the protection layer 5 (e.g., an oxide film such as an SiO₂ film) with an n-type impurity may be used.

The concentration of an n-type impurity in the n-type impurity-containing islands 42 may be 5×10¹⁸ cm⁻³ or more and 5×10²³ cm⁻³ or less, for example. The n-type impurity concentration, the thickness, the size of the island-shaped pattern, etc., of the a-Si film 41 and those of the n-type impurity-containing islands 42 may be adjusted as necessary so that the concentration of the n-type impurity in the first crystalline region C1 obtained after laser annealing is 1×10¹⁸ cm⁻³ or more and 1×10²³ cm⁻³ or less, for example.

Note that the thickness of the n-type impurity-containing islands 42 can be controlled by the deposition time for the film including an n-type impurity, for example. There is no particular limitation on the deposition time, but it may be 0.2 sec or more and 0.6 sec or less, for example. If 0.6 sec or less, a film including an n-type impurity can be more reliably deposited in an island-like pattern. If 0.2 sec or more, it is possible to increase the amount of an n-type impurity to be added, and it is possible to more effectively make Si crystal grains huge.

Then, as shown in FIG. 3(b), an insulating film (e.g., a silicon oxide film) 50 to be the protection layer 5 is formed on the semiconductor film 40. Thereafter, at least a portion of the semiconductor film 40 that is to be the channel region of the TFT is irradiated with a laser beam 30 from above the insulating film 50. An ultraviolet laser such as an XeCl excimer laser (wavelength: 308 nm) or a solid-state laser having a wavelength of 550 nm or less such as the second harmonic (wavelength: 532 nm) of a YAG laser can be used as the laser beam 30.

Through irradiation with the laser beam 30, a region of the semiconductor film 40 that is irradiated with the laser beam 30 is heated to be melted and solidified to form the c-Si region 4c. Thus, the semiconductor layer 4 including the c-Si region 4c is obtained.

In the c-Si region 4c, crystal grains grow in a columnar shape toward the upper surface of the semiconductor film 40. In the second non-crystalline region A2, the second crystalline region C2 that does not substantially include an n-type impurity is formed. In the first non-crystalline region A1, the presence of an n-type impurity (phosphorus atom) activates the migration of Si, thereby making crystal grains huge. As a result, the first crystalline region C1 is formed, where the size of Si crystal grains is larger than the second crystalline region C2. The n-type impurity (phosphorus atom) diffuses in solid phase by the heat of laser irradiation and distributed along the boundaries of Si crystal grains. The concentration gradient region C3 whose n-type impurity concentration decreases from the first crystalline region C1 side toward the second crystalline region C2 side may be generated between the first crystalline region C1 and the second crystalline region C2.

Note that the semiconductor film 40 only needs to include the n-type impurity-containing islands 42 that are arranged discretely. While the a-Si film 41 including the n-type impurity-containing islands 42 arranged discretely on the upper surface thereof is used as the semiconductor film 40 in FIG. 3(a), the structure of the semiconductor film 40 is not limited to the structure shown in FIG. 3(a).

For example, as shown in FIG. 4(a), the a-Si film 41 including the n-type impurity-containing islands 42 arranged discretely on the lower surface (the substrate side surface) thereof may be used as the semiconductor film 40. Such a semiconductor film 40 can be obtained by discretely forming the n-type impurity-containing islands 42 on the gate insulating layer 3, and then forming the a-Si film 41 so as to cover the n-type impurity-containing islands 42. Alternatively, as shown in FIG. 4(b), the a-Si film 41 including the n-type impurity-containing islands 42 arranged discretely therein may be used as the semiconductor film 40. Such a semiconductor film 40 can be obtained by forming an a-Si film 41a, the n-type impurity-containing islands 42 and an a-Si film 41b in this order on the gate insulating layer 3, for example.

The method for forming the n-type impurity-containing islands 42 is not limited to the method of utilizing the initial growth stage by a CVD method. For example, a film including an n-type impurity may be formed, and a plurality of band-shaped patterns extending in the channel width direction may be formed as the n-type impurity-containing islands 42 by a patterning method known in the art. Alternatively, an island-shaped pattern may be used.

There is no particular limitation on the crystallization method using the laser beam 30. For example, an a-Si film may be partially crystallized by focusing the laser beam 30 from the laser light source on only portions of the semiconductor film 40 through a microlens array. In the present specification, this crystallization method is referred to as “partial laser annealing”. Using partial laser annealing, as compared with conventional laser annealing where the entire surface of an a-Si film is scanned by a linear laser beam, it is possible to significantly shorten the amount of time required for crystallization, thereby enhancing mass productivity.

A microlens array includes microlenses arranged in a two-dimensional or one-dimensional array. When a plurality of TFTs are formed on the substrate 1, the laser beam 30 is focused through the microlens array to be incident upon only predetermined regions (irradiated regions) of the semiconductor film 40 that are spaced apart from each other. Each irradiated region is arranged so as to correspond to a portion to be the channel region of the TFT. The position, number, shape, size, etc., of the irradiated regions can be controlled based on the size of the microlens array (which is not limited to lenses that are less than 1 mm), the arrangement pitch thereof, and the positions of the openings in a mask that is arranged on the light source side of the microlens array, etc. Thus, regions of the semiconductor film 40 that are irradiated with the laser beam 30 are heated to be melted and solidified to form the c-Si region 4c. Regions that are not irradiated with the laser beam remain as the a-Si region 4a.

For the more specific method of partial laser annealing and the configuration of the apparatus (including the structure of the microlens array and the mask) used for partial laser annealing, the entire disclosures of International Publication WO2011/055618 pamphlet, International Publication WO2011/132559 pamphlet (Patent Document No. 1), International Publication WO2016/157351 pamphlet (Patent Document No. 2) and International Publication WO2016/170571 pamphlet (Patent Document No. 3) are incorporated herein by reference.

<Method for Manufacturing TFT 101>

Next, an example of a method for manufacturing the TFT 101 will be described.

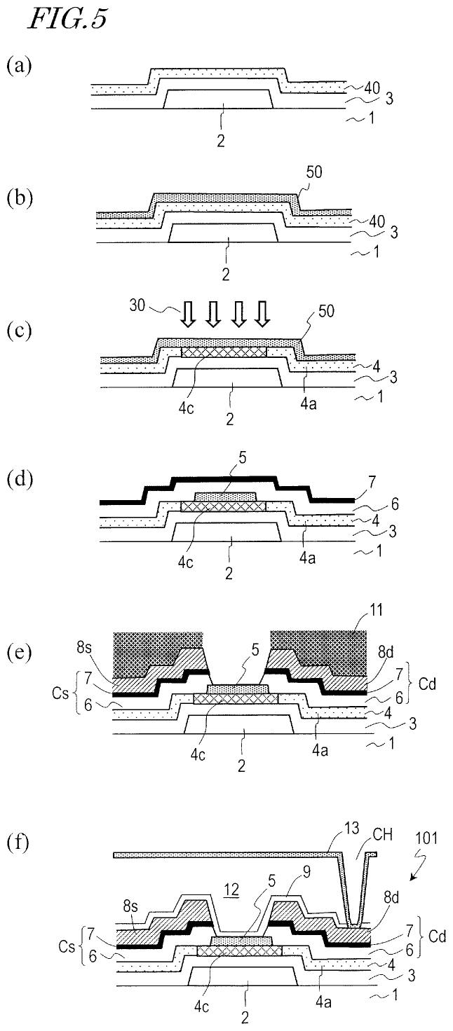

FIG. 5(a) to FIG. 5(f) are schematic step-by-step cross-sectional views illustrating an example of a method for manufacturing the TFT 101.

First, as shown in FIG. 5(a), the gate electrode 2, the gate insulating layer 3 and the semiconductor film 40 to be the active layer of the TFT are formed in this order on the substrate 1.

The substrate 1 may be a substrate having an insulative surface, such as a glass substrate, a silicon substrate or a heat-resistant plastic substrate (resin substrate), for example.

The gate electrode 2 is formed by forming a gate conductive film on the substrate 1, and patterning the gate conductive film. Herein, for example, a gate conductive film (thickness: about 500 nm, for example) is formed on the substrate 1 by a sputtering method, and the metal film is patterned by using a photolithography process known in the art. Wet etching, for example, is used for etching the gate conductive film.

The material of the gate electrode 2 may be a single metal such as molybdenum (Mo), tungsten (W), copper (Cu), chromium (Cr), tantalum (Ta), aluminum (Al), titanium (Ti), or the like, a metal as listed above that contains nitrogen, oxygen or another metal, or a transparent conductive material such as indium tin oxide (ITO).

The gate insulating layer 3 is formed on the substrate 1 including the gate electrode 2 formed thereon by a plasma CVD method, for example. A silicon oxide (SiO₂) layer, a silicon nitride (SiNx) layer, or a laminated film of an SiO₂ layer and an SiNx layer may be formed, for example, as the gate insulating layer 3 (thickness: about 0.4 μm, for example).

The semiconductor film 40 can be formed by a CVD method using the same deposition chamber as the gate insulating layer 3. As described above with reference to FIG. 3 and FIG. 4, the semiconductor film 40 includes the a-Si film 41 and the n-type impurity-containing islands 42. The specific method for forming the semiconductor film 40 is as follows.

First, a non-doped a-Si film 41 is formed using a hydrogen gas (H₂) and a silane gas (SiH₄). The thickness of the a-Si film 41 may be 20 nm or more and 70 nm or less (e.g., 50 nm).

Then, a phosphorus-containing a-Si film including a phosphorus, which is an n-type impurity, is deposited in an island-like pattern on the a-Si film 41 as the n-type impurity-containing islands 42. The phosphorus-containing a-Si film can be formed by using a mixed gas of silane, hydrogen and phosphine (PH₃) as a source gas, for example. It can be deposited in an island-like pattern by controlling the deposition time, for example, by utilizing the initial growth stage of deposition by a CVD method, as described above.

Then, as shown in FIG. 5(b), the insulating film 50 to be the protection layer 5 is formed on the semiconductor film 40. The insulating film 50 can also be formed by a CVD method using the same deposition chamber as the gate insulating layer 3. Herein, an SiO₂ film, for example, is formed as the insulating film 50. The thickness of the insulating film 50 may be 30 nm or more and 300 nm or less, for example. Thereafter, although not shown in the figures, a dehydrogenation annealing treatment (e.g., 450° C., 60 min) may be performed on the semiconductor film 40.

Then, as shown in FIG. 5(c), the semiconductor film is irradiated with the laser beam 30 from above the insulating film 50, thereby crystallizing at least a portion of the semiconductor film 40 to be the channel region of the TFT. An XeCl excimer laser (wavelength: 308 nm) may be used as the laser beam 30, for example.

In this example, only a portion of the semiconductor film 40 (including a portion to be the channel region of the TFT) is irradiated with the laser beam 30 (partial laser annealing). A region of the semiconductor film 40 that is irradiated with the laser beam 30 is heated to be melted and solidified to form the c-Si region 4c. Regions that are not irradiated with the laser beam remain as the a-Si region 4a.

As described above with reference to FIG. 3, regions of the semiconductor film 40 where the n-type impurity-containing islands 42 are arranged are irradiated with the laser beam 30, and therefore crystal grains of a larger grain diameter grow therein than in regions where the n-type impurity-containing islands 42 are absent. Therefore, the c-Si region 4c includes the second crystalline region C2 that does not include phosphorus, and the first crystalline region C1 that includes phosphorus and that has a larger grain diameter of Si crystal grains than the second crystalline region C2. As viewed from the direction normal to the substrate 1, the first crystalline regions C1 are arranged in an island-like pattern corresponding to the island-shaped pattern of the n-type impurity-containing islands 42, for example.

Then, as shown in FIG. 5(d), the insulating film 50 is patterned to obtain the protection layer 5 that covers a portion of the semiconductor layer 4 to be the channel region. On the source side and the drain side of the portion to be the channel region, a portion of the c-Si region 4c is exposed from the protection layer 5. The exposed portion is to be a connecting portion with the contact layers Cs and Cd.

Then, an Si film for the contact layers is formed on the semiconductor layer 4. Herein, an intrinsic first a-Si layer 6 (thickness: about 0.1 μm, for example) and an n⁺-type second a-Si layer 7 (thickness: about 0.05 μm, for example) including an n-type impurity (herein, phosphorus) are deposited in this order by a plasma CVD method. A hydrogen gas and a silane gas are used as the source gas of the first a-Si layer 6. A mixed gas of silane, hydrogen and phosphine (PH₃) is used as the source gas of the second a-Si layer 7.

Next, as shown in FIG. 5(e), a conductive film (thickness: about 0.3 μm, for example) for source and drain electrodes and a resist mask 11 are formed on the second a-Si layer 7. The conductive film for source and drain electrodes can be formed by a method similar to that for the gate conductive film by using a material similar to the gate conductive film.

Then, the conductive film for source and drain electrodes and the Si film for a contact layer (herein, the first a-Si layer 6 and the second a-Si layer 7) are patterned by dry etching, for example, using the resist mask 11. Thus, the source electrode 8s and the drain electrode 8d are formed from the conductive film (source-drain separation step). The first contact layer Cs and the second contact layer Cd are formed from the Si film for the contact layer. In this example, the first a-Si layer 6 and the second a-Si layer 7 are both divided into a portion to be the first contact layer Cs and a portion to be the second contact layer Cd. Since the protection layer 5 functions as an etch stop during the patterning, a portion of the semiconductor layer 4 that is covered by the protection layer 5 is not etched. Thereafter, the resist mask 11 is peeled off the substrate 1. Thus, the TFT 101 is manufactured.

Note that in order to inactivate dangling bonds in the c-Si region 4c and reduce the defect density, a hydrogen plasma treatment may be performed on the c-Si region 4c after the source-drain separation step.

When the TFT 101 is used as a pixel TFT of an active matrix substrate, an interlayer insulating layer is formed so as to cover the TFT 101 as shown in FIG. 5(f). Herein, an inorganic insulating layer (passivation film) 9 and an organic insulating layer 12 are formed as the interlayer insulating layer.

A silicon oxide layer, a silicon nitride layer, or the like, may be used as the inorganic insulating layer 9. Herein, an SiNx layer (thickness: about 200 nm, for example) is formed by a CVD method, for example, as the inorganic insulating layer 9. The inorganic insulating layer 9 is in contact with the protection layer 5 (in the gap) between the source electrode 8s and the drain electrode 8d.

The organic insulating layer 12 may be an organic insulating film (thickness: 1 to 3 μm, for example) including a photosensitive resin material, for example. Thereafter, the organic insulating layer 12 is patterned to form an opening. Then, the inorganic insulating layer 9 is etched (dry etched) using the organic insulating layer 12 as a mask. Thus, a contact hole CH that reaches the drain electrode 8d is formed in the inorganic insulating layer 9 and the organic insulating layer 12.

Then, a transparent conductive film is formed on the organic insulating layer 12 and in the contact hole CH. A metal oxide such as indium-tin oxide (ITO), indium-zinc oxide and ZnO can be used as the material of the transparent electrode film. Herein, an indium-zinc oxide film (thickness: about 100 nm, for example) is formed as the transparent conductive film by a sputtering method, for example.

Thereafter, the transparent conductive film is patterned by wet etching, for example, to obtain pixel electrodes 13. The pixel electrodes 13 are arranged spaced apart from each other for each pixel. Each pixel electrode 13 is in contact with the drain electrode 8d of the corresponding TFT in the contact hole. Although not shown in the figures, the source electrode 8s of the TFT 101 is electrically connected to the source bus line (not shown), and the gate electrode 2 is electrically connected to the gate bus line (not shown).

Note that while phosphorus is used as an n-type impurity in the method shown in FIG. 5, another n-type impurity such as arsenic may be used instead. Note however that phosphorus easily diffuses in solid phase, it is possible to achieve more significant effects (an improvement in the channel mobility and a reduction in GIDL) by using phosphorus.

Each of the semiconductor layer 4, the first contact layer Cs and the second contact layer Cd may be patterned in an island-like pattern in the region where the TFT 101 is formed (the TFT formation region). Alternatively, the semiconductor layer 4, the first contact layer Cs and the second contact layer Cd may be extended to a region other than the region where the TFT 101 is formed (the TFT formation region). For example, the semiconductor layer 4 may extend so as to overlap with the source bus line, which is connected to the source electrode 8s. Only a portion of the semiconductor layer 4 that is located in the TFT formation region needs to include the c-Si region 4c, and a portion that is extended to a region other than the TFT formation region may be the a-Si region 4a.

The crystallization method for the semiconductor film 40 is not limited to the partial laser annealing described above. A part or whole of the semiconductor film 40 may be crystallized by using another method known in the art.

<Variation>

While the semiconductor film 40 is irradiated with the laser beam 30 with the semiconductor film 40 covered by the insulating film 50 in the method shown in FIG. 5, it may be irradiated with the laser beam 30 with the semiconductor film 40 exposed. For example, the crystallization step using the laser beam 30 may be performed after the formation of the semiconductor film 40 and before the formation of the insulating film 50.

FIG. 6(a) to FIG. 6(c) are schematic step-by-step cross-sectional views illustrating another method for manufacturing the TFT 101.

First, as shown in FIG. 6(a), the gate electrode 2, the gate insulating layer 3 and the semiconductor film 40 are formed on the substrate 1 by a method similar to FIG. 5(a). In this state, as shown in FIG. 6(b), the semiconductor film 40 is irradiated with the laser beam 30 to crystallize the semiconductor film 40, thereby obtaining the semiconductor layer 4 including the c-Si region 4c. The crystallization method may be similar to FIG. 5(c). Thereafter, as shown in FIG. 6(c), the protection layer 5 is formed on the semiconductor layer 4. Thereafter, although not shown in the figures, the first contact layer Cs, the second contact layer Cd, the source electrode 8s and the drain electrode 8d are formed by a method similar to FIG. 5(d) to FIG. 5(e).

When the crystallization step using the laser beam 30 is performed with the semiconductor film 40 exposed, the crystal grain diameters of the first crystalline region C1 and the second crystalline region C2 can be larger than those when the crystallization step is performed with the semiconductor film 40 covered by the insulating film 50, etc. Therefore, it is possible to more effectively improve the channel mobility of the TFT 101.

<TFT Characteristics of Embodiment Example and Reference Example>

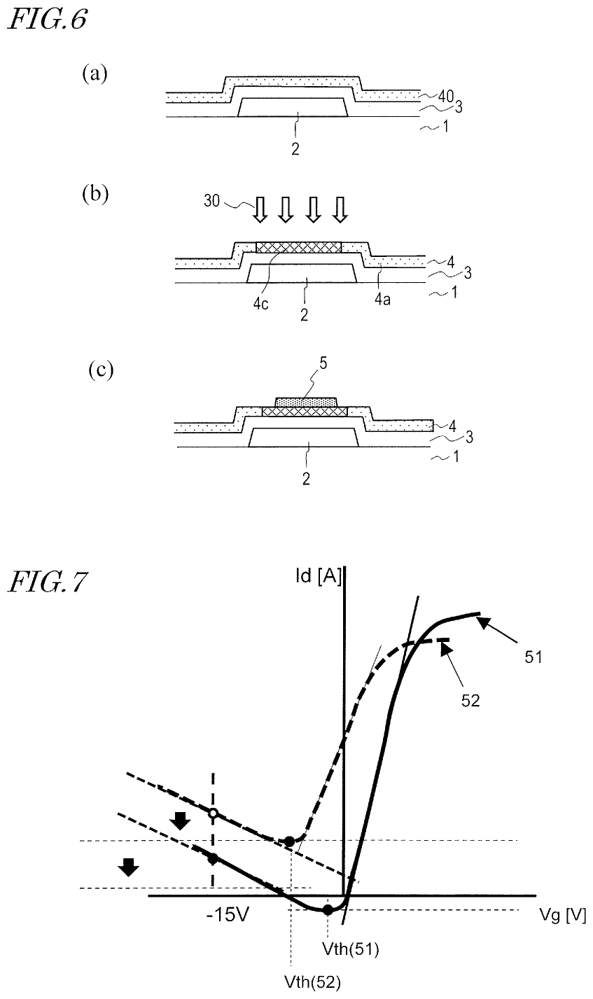

FIG. 7 is a schematic diagram illustrating the V-I (gate voltage Vg-drain current Id) characteristic of a TFT of Embodiment Example and that of a TFT of Reference Example. In FIG. 7, the characteristic of the TFT 101 and that of the TFT of Reference Example are denoted by the solid line 51 and the broken line 52, respectively. The TFT of Embodiment Example has a configuration similar to that of the TFT 101, and is formed by the method described above with reference to FIG. 5. The TFT of Reference Example has a channel region that does not have the first crystalline region C1, i.e., that is composed only of the second crystalline region C2. The TFT of Reference Example is formed by the same method as the TFT of Embodiment Example except that the n-type impurity-containing islands 42 are not formed in the semiconductor film 40.

As shown in FIG. 7, with the TFT 101, the channel mobility of the c-Si region 4c is improved, and the ON current Id is higher than the TFT of Reference Example. The threshold voltage Vth (51) of the TFT of Embodiment Example is shifted in the positive direction relative to the threshold voltage Vth (52) of the TFT of Reference Example. Moreover, with the TFT of Embodiment Example, since GIDL is improved, the OFF current Ioff is reduced as compared with the TFT of Reference Example.

### Second Embodiment

A TFT of a second embodiment is different from the TFT of the first embodiment in that it does not have the protection layer 5, i.e., it has a channel-etched structure.

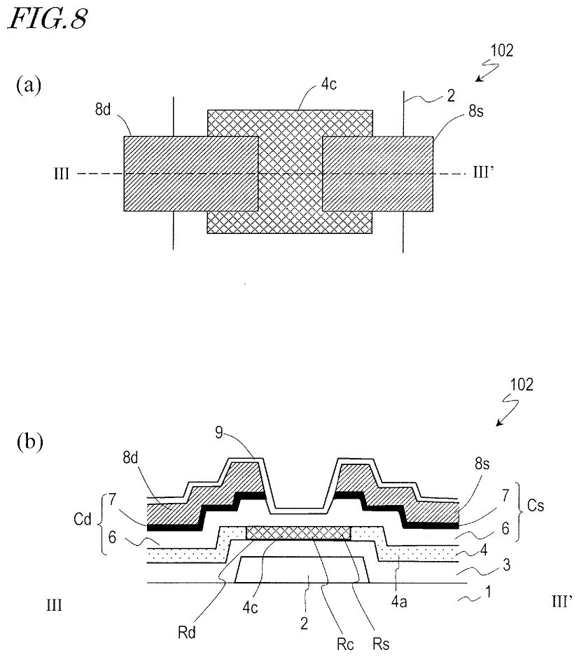

FIG. 8(a) is a schematic plan view of a thin film transistor (TFT) 102 in a semiconductor device of the present embodiment, and FIG. 8(b) is a cross-sectional view of the TFT 102 taken along line III-III′. In FIG. 8, like elements to FIG. 1 are denoted by like reference signs. Hereinbelow, description of elements similar to those of the TFT 101 shown in FIG. 1 may be omitted.

The TFT 102 is a channel-etched type TFT having a bottom gate structure, for example. The TFT 102 does not include an insulating film (the protection layer 5 shown in FIG. 1, for example) that is arranged between the channel region Rc of the semiconductor layer 4 and the first contact layer Cs and the second contact layer Cd and covers the channel region Rc.

Also in the TFT 102, the c-Si region 4c of the semiconductor layer 4 includes the first crystalline regions C1 and the second crystalline regions C2. The c-Si region 4c has a polycrystal structure described above with reference to FIG. 1 and FIG. 2, for example.

For example, the first contact layer Cs and the second contact layer Cd in the TFT 102 include the first a-Si layer 6, which is an intrinsic a-Si layer arranged so as to be in contact with the semiconductor layer 4, and the second a-Si layer 7, which is an n⁺-type a-Si layer arranged on the first a-Si layer 6. The second a-Si layers 7 of the first contact layer Cs and the second contact layer Cd are arranged spaced apart from each other. On the other hand, the first a-Si layers 6 of the first contact layer Cs and the second contact layer Cd are not separated. That is, the first a-Si layer 6 is in contact with the channel region Rc of the semiconductor layer 4. A portion of the first a-Si layer 6 that is located between the source electrode 8s and the drain electrode 8d (a portion of the semiconductor layer 4 that is in contact with the channel region Rc) may become thinner than other portions through etching in the source-drain separation step. Otherwise, the structure is similar to the TFT 101 shown in FIG. 1.

Note that the first a-Si layers 6 of the first contact layer Cs and the second contact layer Cd may also be arranged spaced apart from each other, as are the second a-Si layers 7. In that case, the channel region Rc is in contact with the inorganic insulating layer 9 covering the TFT 102, for example. A surface portion of the channel region Rc of the semiconductor layer 4 may become thinner (overetched) than other portions through the source-drain separation step.

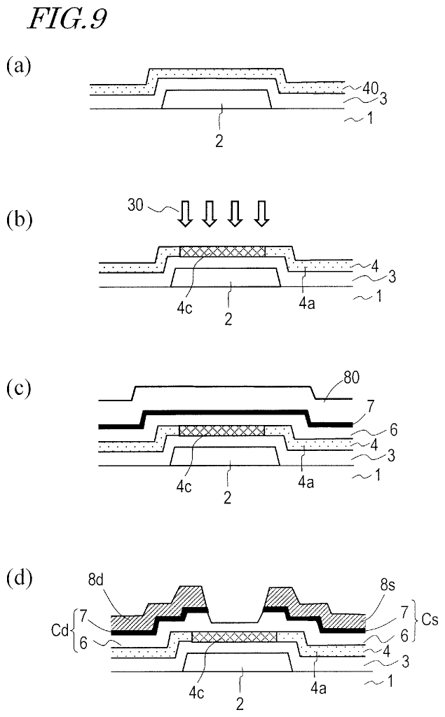

FIGS. 9(a) to 9(d) are step-by-step cross-sectional views illustrating an example of a method for manufacturing the TFT 102.

First, as shown in FIG. 9(a), the gate electrode 2, the gate insulating layer 3 and the semiconductor film 40 are formed on the substrate 1. Then, as shown in FIG. 9(b), the semiconductor film 40 is irradiated with the laser beam 30, thereby obtaining the semiconductor layer 4 including the c-Si region 4c. These steps are similar to the steps described above with reference to FIGS. 6(a) and 6(b). In the present embodiment, since the laser crystallization step is performed while the semiconductor film 40 is exposed, the size of crystal grains can be made larger than when the laser crystallization step is performed while the semiconductor film 40 is covered by a protection film, or the like.

Then, as shown in FIG. 9(c), the first a-Si layer 6, the second a-Si layer 7 and a conductive film 80 for source and drain electrodes are formed in this order so as to cover the semiconductor layer 4. Methods for forming these films are similar to those of the embodiment described above.

Thereafter, as shown in FIG. 9(d), the second a-Si layer 7 and the conductive film 80 are patterned by dry etching, for example, using a resist mask (not shown). In this process, a surface portion of the first a-Si layer 6 may be removed. Thus, the first contact layer Cs and the second contact layer Cd are obtained from the first a-Si layer 6 and the second a-Si layer 7, and the source electrode 8s and the drain electrode 8d are obtained from the conductive film 80.

Note that it is preferred that the etching is performed under conditions (e.g., the etching time) such that the first a-Si layer 6 is not removed across the thickness direction. Thus, it is possible to suppress the lowering of the TFT characteristics due to the channel region Rc of the semiconductor layer 4 being damaged by the etching.

The structure of the TFT of the present invention is not limited to the structure described above with reference to FIG. 1 and FIG. 8. A TFT of an embodiment of the present invention only needs to include the semiconductor layer 4 having a polycrystal structure as shown in FIG. 1 and FIG. 2. Such a TFT may have a top gate structure including a gate electrode on the opposite side of the semiconductor layer relative to the substrate. In that case, instead of the contact layers Cs and Cd, portions of the semiconductor layer on the opposite sides of the channel region may be doped with an impurity to provide a source region and a drain region.

### INDUSTRIAL APPLICABILITY

Embodiments of the present invention are widely applicable to devices and electronic appliances having TFTs. For example, embodiments of the present invention are applicable to circuit substrates such as active matrix substrates, display devices such as liquid crystal display devices, organic electroluminescence (EL) display devices and inorganic electroluminescence display devices, radiation detectors, imaging devices such as image sensors, electronic devices such as image input devices and fingerprint reader devices, etc.

### REFERENCE SIGNS LIST

1: Substrate, 2: Gate electrode, 3: Gate insulating layer, 4: Semiconductor layer, 4a: a-Si region, 4c: C-Si region, 5: Protection layer, 6: First a-Si layer, 7: Second a-Si layer, 8d: Drain electrode, 8s: Source electrode, 9: Inorganic insulating layer, 11: Resist mask, 12: Organic insulating layer, 13: Pixel electrode, 30: Laser beam, 40: Semiconductor film, 41, 41a, 41b: a-Si film, 42: n-type impurity-containing island, 50: Insulating film, 80: Conductive film, A1: First non-crystalline region, A2: Second non-crystalline region, C1: First crystalline region, C2: Second crystalline region, C3: Concentration gradient region, Cs: First contact layer, Cd: Second contact layer, P1: Si crystal grains, P2: Si crystal grains, Rc: Channel region, Rs: First region, Rd: Second region

1. A thin film transistor comprising:
a substrate;
a gate electrode supported on the substrate;
a semiconductor layer including a crystalline silicon region, wherein the crystalline silicon region includes a first region and a second region, and includes a channel region that is located between the first region and the second region and overlaps with the gate electrode as viewed from a direction normal to the substrate;
a gate insulating layer that provides insulation between the gate electrode and the semiconductor layer;
a source electrode electrically connected to the first region; and
a drain electrode electrically connected to the second region, wherein:
the channel region includes a plurality of first crystalline regions and at least one second crystalline region, wherein the first crystalline regions are separated from each other by the at least one second crystalline region;
each of the first crystalline regions includes an n-type impurity at a higher concentration than the at least one second crystalline region; and
an average grain diameter of silicon crystal grains in each of the first crystalline regions is larger than an average grain diameter of silicon crystal grains in the at least one second crystalline region.

2. The thin film transistor according to claim 1, wherein the at least one second crystalline region does not substantially include an n-type impurity.

3. The thin film transistor according to claim 1, wherein the semiconductor layer further includes a concentration gradient region in a boundary between the at least one second crystalline region and one of the first crystalline regions, wherein a concentration of an n-type impurity of the concentration gradient region decreases from the one of the first crystalline regions toward the at least one second crystalline region.

4. The thin film transistor according to claim 1, wherein silicon crystal grains in the first crystalline regions and the at least one second crystalline region have a columnar shape that extends in a thickness direction of the semiconductor layer.

5. The thin film transistor according to claim 1, wherein the average grain diameter of silicon crystal grains in each of the first crystalline regions is 50 nm or more and 170 nm or less, and the average grain diameter of silicon crystal grains in the at least one second crystalline region is 30 nm or more and 100 nm or less.

6. The thin film transistor according to claim 1, wherein the semiconductor layer is formed by laser-annealing an amorphous silicon film wherein islands including the n-type impurity are arranged discretely on an upper surface or a lower surface of the amorphous silicon film.

7. The thin film transistor according to claim 1, wherein the thin film transistor further includes a protection layer that covers the channel region between the semiconductor layer and the source electrode and the drain electrode.

8. The thin film transistor according to claim 1, wherein the semiconductor layer further includes a non-crystalline silicon region.

9. The thin film transistor according to claim 1, wherein the n-type impurity includes phosphorus.

10. A semiconductor device comprising the thin film transistor according to claim 1, wherein:
the semiconductor device has a display area including a plurality of pixels; and
the thin film transistor is arranged in each of the pixels of the display area.

11. A method for manufacturing a thin film transistor supported on a substrate, comprising:
a step of forming a semiconductor layer to be an active layer of the thin film transistor, wherein the step of forming the semiconductor layer includes:
a semiconductor film formation step (A) of forming a semiconductor film including an n-type impurity, the step (A) including a step (a1) of forming a non-crystalline silicon film on the substrate, and a step (a2), before or after the step (a1), of discretely forming a plurality of n-type impurity-containing islands including the n-type impurity; and
a crystallization step (B) of crystallizing at least a portion of the semiconductor film through irradiation with a laser beam so as to form a crystalline silicon region in the at least a portion of the semiconductor film, wherein, in the at least a portion of the semiconductor film, a first crystalline region is formed in a portion where each of the n-type impurity-containing islands is located and a second crystalline region is formed in a portion where any of the n-type impurity-containing islands are not located, the first crystalline region having a larger crystal grain diameter than the second crystalline region.

12. The method for manufacturing a thin film transistor according to claim 11, wherein in the step (a2), the n-type impurity-containing islands are formed by utilizing an initial growth stage of deposition by a CVD method.

13. The method for manufacturing a thin film transistor according to claim 12, further comprising, between the step (A) and the step (B), a step of forming an insulating film that covers the semiconductor film, wherein in the step (B), the semiconductor film is irradiated with the laser beam from above the insulating film.
